(19) United States
(12) Patent Application Publication
(10) Pub. No.: US 2012/0003759 A1
(43) Pub. Date: Jan. 5, 2012

(54) ENDPOINT CONTROL DURING CHEMICAL MECHANICAL POLISHING BY DETECTING INTERFACE BETWEEN DIFFERENT LAYERS THROUGH SELECTIVITY CHANGE

(75) Inventors: Xiaoyuan Hu, Milpitas, CA (US); Zhihong Wang, Santa Clara, CA (US); Wen-Chiang Tu, Mountain View, CA (US)

(73) Assignee: APPLIED MATERIALS, INC., Santa Clara, CA (US)

(21) Appl. No.: 13/163,139

(22) Filed: Jun. 17, 2011

Related U.S. Application Data
(60) Provisional application No. 61/360,356, filed on Jun. 30, 2010.

(51) Int. Cl. H01L 21/66

(52) U.S. Cl. 438/8; 257/E21.53

(57) ABSTRACT

Embodiments described herein relate to methods of detecting an endpoint for a target substrate during chemical mechanical polishing process. In one embodiment, the method includes polishing one or more target substrates at a first film removal rate to provide reference spectra, polishing one or more target substrates at a second film removal rate to provide current spectra of the one or more target substrates, wherein the second film removal rate is different from the first film removal rate, identifying an interface transition between different layers formed on the one or more target substrates using a sequence of endpoint values obtained based on the reference spectra collected during polishing of the one or more reference substrates, and comparing each current spectrum obtained from current spectra of the one or more target substrates to the reference spectra to obtain the sequence of endpoint values. After identifying the interface transition between different layers formed on the one or more target substrates, the one or more target substrates is optionally overpolished to past a target polishing thickness.

### CROSS-REFERENCE TO RELATED APPLICATIONS

This application claims benefit of U.S. provisional patent application Ser. No. 61/360,356, filed Jun. 30, 2010, which is herein incorporated by reference.

### BACKGROUND OF THE INVENTION

1. Field of the Invention

Embodiments described herein relate to removing material from a substrate. More particularly, the embodiments described herein relate to endpoint control during chemical mechanical polishing.

2. Description of the Related Art

Integrated circuits have evolved into complex devices that can include millions of components (e.g., transistors, capacitors and resistors) on a single chip. The demand for greater circuit density necessitates a reduction in the dimensions of the integrated circuit components, e.g., sub-micron dimensions and the use of various materials to fabricate devices in order to achieve much faster and better electrical performance, such as materials with higher conductivity used in metal lines, materials with lower permittivity (low-k, dielectric constant) used as insulating materials, etc. For integrated circuit fabrication, metal interconnects with low resistance, such as copper and aluminum interconnects, provide conductive paths between the integrate circuit components on integrated circuit devices. Generally, metal interconnects are electrically isolated from each other by a dielectric bulk insulating material. At sub-micron dimensions, capacitive coupling potentially occurs between adjacent metal interconnects, which may cause cross talk and/or resistance-capacitance (RC) delay and degrade the overall performance of the integrated circuit.

Some integrated circuit components include multilevel interconnect structures, for example, dual damascene structures. Typically, dual damascene structures have dielectric bulk insulating layers and conductive metal layers, such as low dielectric constant materials and conductive copper layers, stacked on top of one another. Vias and/or trenches are etched into the dielectric bulk insulating layer and the conductive metal layers are subsequently filled into the vias and/or trenches and planarized, such as by a chemical mechanical planarization process (CMP), so that the conducting metal materials are only left in the vias and/or trenches. In the dual damascene approach, a rather complex dielectric stack that includes a sequence of hard mask, low-k dielectrics, and etch stop layers, etc., may be required.

A challenge during CMP is determining whether the polishing process is complete, i.e., whether a substrate layer has been planarized to a desired flatness or thickness, or when a desired amount of material has been removed. Overpolishing (removing too much) of a conductive layer or film may result in increased circuit resistance. On the other hand, underpolishing (removing too little) of a conductive layer may result in electrical shorting. Variations in the slurry composition, the polishing pad condition, the relative speed between the polishing pad and the substrate, and the load on the substrate can cause variations in the material removal rate. These variations plus incoming thickness variation cause variations in the time needed to reach the polishing endpoint. Therefore, the polishing endpoint cannot be determined merely as a function of polishing time or predetermined thickness.

More recently, in-situ optical monitoring of the substrate using spectrum based endpoint detecting techniques has been performed in order to enhance detection of the polishing endpoint. In operation, a computing device is used to receive, for example, a signal that carries information describing a spectrum of light received by a light detector for a particular flash of a light source. The spectrum of light reflected from the substrate evolves as polishing progresses due to changes in the thickness of the outermost layer, thus yielding a sequence of time-varying spectra. Particular spectra are exhibited by particular thicknesses of the layer stack. However, for some specific film stacks, endpoint determination becomes quite difficult due to minimal spectra change during polishing which may be masked out by wafer-to-wafer and lot-to-lot variation. For example, for a film stack of hardmask/ultra low-k dielectric/barrier layer, the spectra usually change significantly during polishing of barrier layer and hard-mask layers, but the spectra change can be very small during ultra low-k dielectric polishing. Therefore, the polishing endpoint cannot be determined merely as a function of the spectrum.

Therefore, there is a need for an improved method for endpoint detection during chemical mechanical polishing.

### SUMMARY OF THE INVENTION

Embodiments described herein relate to removing material from a substrate. More particularly, the embodiments described herein relate to a method of detecting an endpoint for a target substrate during chemical mechanical polishing process. In one embodiment, the method includes polishing one or more reference substrates at a first film removal rate to provide reference spectra, polishing one or more target substrates at a second film removal rate to provide current spectra of the one or more target substrates, wherein the second film removal rate is different from the first film removal rate, identifying an interface transition between different layers formed on the one or more target substrates using a sequence of endpoint values obtained based on the reference spectra collected during polishing of the one or more reference substrates, and comparing each current spectrum obtained from current spectra of the one or more target substrates to the reference spectra to obtain the sequence of endpoint values. In one aspect, after comparing step is done, identifying an interface transition between different layers formed on the one or more target substrates based on a sequence of best-matched reference spectra. After identifying the interface transition between different layers formed on the one or more target substrates, the one or more target substrates is optionally overpolished to a desired thickness depending upon application.

In another embodiment, a method of detecting an endpoint for a target substrate during chemical mechanical polishing process is provided. In one embodiment, the method of detecting an endpoint for a target substrate during chemical mechanical polishing process includes polishing a target substrate containing multiple film layers deposed thereon, and terminating polishing of the target substrate when an endpoint is reached, the endpoint selected in response to information compiled from spectral analysis identifying at least one interface between layers during polishing of at least one reference substrate.

In yet another embodiment, a method for processing a target substrate during chemical mechanical polishing process is provided. The method includes polishing and measuring a reference substrate using a first slurry to provide reference spectra at different platen revolutions, polishing and measuring a target substrate using a second slurry to provide current spectra at different platen revolutions, wherein the second slurry has a film removal rate different from that of the first slurry, comparing current spectra of the target substrate to reference spectra to generate a sequence of best-matched reference spectra at different polishing times, and identifying an interface transition between different layers in the target substrates using a sequence of endpoint values collected during polishing of the reference substrate based on the sequence of best-matched reference spectra.

### BRIEF DESCRIPTION OF THE DRAWINGS

So that the manner in which the above recited features of the present invention can be understood in detail, a more particular description of the invention, briefly summarized above, may be obtained by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates an example of a polishing apparatus having two polishing heads;

FIG. 2 illustrates a schematic cross-sectional view of a substrate containing dual damascene structures;

FIG. 3 illustrates a method in accordance with the present invention for obtaining a target spectrum;

FIG. 4 illustrates a method in accordance with the present invention for selecting a reference spectrum for a particular target thickness and particular spectrum-based endpoint determination logic;

FIG. 5 illustrates a sequence of endpoint values collected during polishing of a target wafer having a known dielectric film stack of FIG. 2 at different times; and

FIG. 6 illustrates a comparison of a resulting thickness of a metal line in a dielectric base layer with different initial thickness after processing with a prior art and instant endpoint technique; and

FIG. 7 illustrates a method in accordance with the present invention for endpoint detection using identified film interface between different layers.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

As discussed previously, variations in the polishing pad condition and the relative speed between the polishing pad and the substrate, etc. can cause variations in the material removal rate. If multiple wafers are to be polished simultaneously, e.g., on the same polishing pad, variations in the initial thickness of the substrate layer, polishing rate variations due to the polishing pad condition, and the relative speed between the polishing pad and the substrate, etc., can lead to the substrates reaching their target thickness at different times. Similarly, if polishing is halted simultaneously for the substrates, then some substrates may not be at the desired thickness. On the other hand, if polishing of the substrates is stopped at different times, then some substrates may have defects and the polishing apparatus will likely be operating at lower throughput.

As will be discussed below, by identifying interfaces between different layers, from in-situ measurements, a projected endpoint time for a target thickness or a projected thickness for target endpoint time can be determined for each substrate, and the polishing rate for at least one substrate can be adjusted so that the substrates achieve closer endpoint conditions. By “closer endpoint conditions,” it is meant that the substrates would reach their target thickness closer to the same time than without such adjustment, or if the substrates halt polishing at the same time, that the substrates would have closer to the same thickness than without such adjustment.

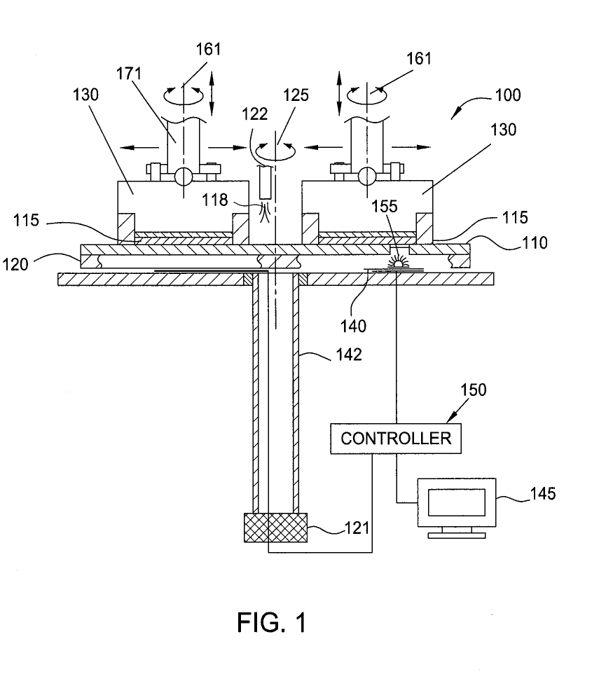

FIG. 1 illustrates a partial cross-sectional view of an exemplary polishing apparatus 100. The polishing apparatus 100 includes a rotatable disk-shaped platen 120 on which a polishing pad 110 is situated. An optical access 155 formed through the polishing pad 110 is provided by including an aperture (i.e. a hole that runs through the pad) or a solid window. The platen 120 is operable to rotate about an axis 125 through a motor 121 turning a drive shaft 142 to rotate the platen 120. The polishing apparatus 100 may include a combined slurry/rinse arm 122. During polishing, the arm 122 is operable to dispense a polishing liquid 118, such as a slurry, onto the polishing pad 110.

The polishing apparatus 100 generally includes at least one carrier head, although two carrier heads 130 is shown in FIG. 1. Each carrier head 130 is operable to hold a substrate 115 against the polishing pad 110. Each carrier head 130 can have independent control of at least one polishing parameters, for example the force used to press the substrate 115 against the polishing pad 110 and platen 120, associated with each respective substrate 115. Each carrier head 130 is suspended from a support structure 171 and is connected by a drive shaft to a carrier head rotation motor (not shown) which rotates the carrier head 130 and substrate 115 retained therein about an axis 161. Optionally, each carrier head 130 may oscillate laterally or in a sweeping motion. In operation, the platen 120 is rotated about its central axis 125, and each carrier head 130 is rotated about its central axis 161. The carrier head 130 may additionally be translated laterally across the top surface of the polishing pad 110. One suitable carrier head assembly is a TITAN HEAD™ carrier head available from Applied Materials, Inc., located in Santa Clara, Calif.

While only two carrier heads 130 are shown, more carrier heads can be provided to hold additional substrates so that the surface area of polishing pad 110 may be used efficiently. Thus, the number of carrier head assemblies adapted to hold substrates for a simultaneous polishing process can be based, at least in part, on the surface area of the polishing pad 110. While only one slurry/rinse arm 122 is shown, additional nozzles (not shown), such as one or more dedicated slurry arms for each carrier head, can be used and may be provided at a desired location in favor of slurry distribution. Embodiments of the present invention may be practiced in a suitable adapted REFLEXION®, REFLEXION® GT, REFLEXION® LK, and MIRRA MESA® CMP systems, available from Applied Materials, Inc., located in Santa Clara, Calif. Additionally, the present invention may also be practiced in suitable adapted CMP systems available from other manufacturers.

The polishing apparatus also includes an in-situ monitoring system 140, which can be used to determine whether to adjust a polishing rate as discussed below. The in-situ monitoring system 140 may include an optical monitoring system, e.g., a laser or spectrographic monitoring system, or an eddy current monitoring system.

In one embodiment, the monitoring system 140 is an optical monitoring system. The optical monitoring system may include one or more of the components (not shown) such as a light source, a light detector, and circuitry for sending and receiving signals to and from the light source and light detector.

In operation, light is emitted from the light source through the optical access 155 in the polishing pad 110 is reflected by the substrate 115, and the reflected light travels back through the optical access 155 to the light detector. The light source can be operable to emit white light. In one implementation, the white light emitted includes light having wavelengths between about 200 nanometers and about 800 nanometers. One suitable light source is a xenon lamp or a xenon mercury lamp.

The light detector can be a spectrometer, such as a grating spectrometer. The spectrometer is an optical instrument for measuring intensity of light over a portion of the electromagnetic spectrum. A spectrometer has an output signal indicative of the intensity of the light as a function of wavelength (or frequency). The light source and light detector can be connected to a computing device 150, e.g., a controller, operable to control their operation and receive their signals. The computing device 150 can include a microprocessor 145 situated near the polishing apparatus, e.g., a programmable logic controller. With respect to control, the computing device 150 can, for example, synchronize activation of the light source of the monitoring system 140 with the rotation of the platen 120.

In some embodiments, a sensor (not shown) of the in-situ monitoring system 140 can be installed in and rotates with the platen 120. In this embodiment, the motion of the platen 120 relative to the substrate 115 will cause the sensor to scan across the substrate. In other embodiments, the sensor of the in-situ monitoring system 140 is stationary and positioned below the substrate 115. In this embodiment, the in-situ monitoring system 140 may obtain a measurement each time that the optical access 155 formed through the platen is rotated into alignment with the sensor of the monitoring system 140 to permit light from the monitoring system 140 to be sent to and reflected back from the substrate 115 through the platen 120.

In one embodiment, as the platen 120 rotates, the computing device 150 can cause the light source to emit a series of flashes starting just before and ending just after the substrate 115 passes over the in-situ monitoring system 140 or the optical access 155 in the platen 120 is aligned with the sensor of the in-situ monitoring system 140. Alternatively, the computing device 150 can cause the light source to emit light continuously starting just before and ending just after the substrate 115 passes over the in-situ monitoring system 140 or the optical access 155 in the platen 120 is aligned with the sensor of the in-situ monitoring system 140. In either case, the signal from the detector can be integrated over a sampling period to generate spectra measurements at a sampling frequency.

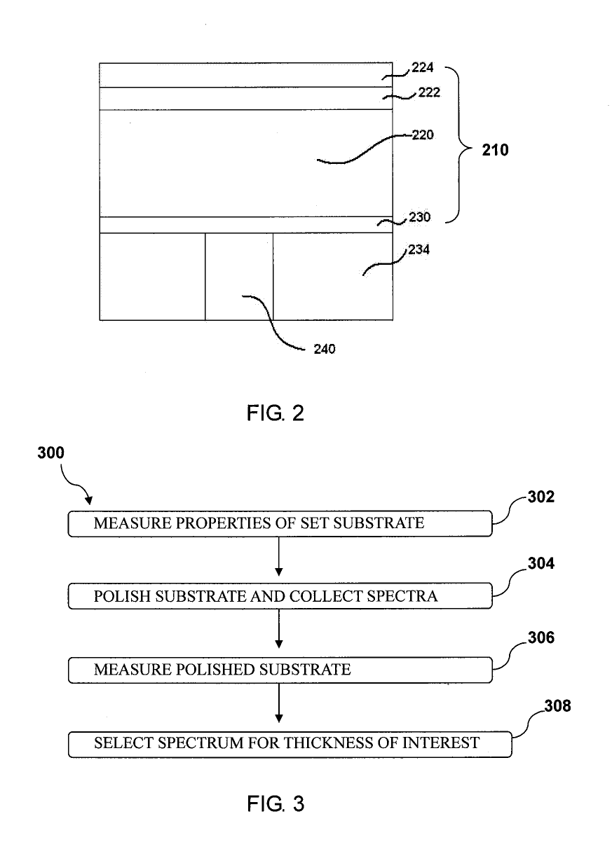

In operation, the computing device 150 can receive, for example, a signal that carries information describing a spectrum of the light received by the light detector for a particular flash of the light source or time frame of the detector. Thus, this spectrum is a spectrum measured in-situ during polishing. Without being limited to any particular theory, the spectrum of light reflected from the substrate 115 evolves as polishing progresses due to changes in the thickness of the outermost layer, thus yielding a sequence of time-varying spectra. Particular spectra are exhibited by particular thicknesses of the layer stack. However, as discussed previously, for some specific film stacks, endpoint determination may become difficult due to minimal spectra change during polishing which may be masked out by wafer-to-wafer and lot-to-lot variation. For example, in a film stack of hardmask/bulk dielectric layer/bottom barrier layer as shown below in FIG. 2, the spectra may change significantly during polishing of the hardmask layers 222, 224 but the spectra change is very small during the bulk dielectric layer 220 polishing (will be discussed below in conjunction with FIG. 3), thereby rendering the endpoint detection at desired final thickness difficult.

FIG. 2 illustrates a substrate 200 containing an exemplary dual damascene structure which may be benefit from the present invention. The substrate 200 generally includes a dielectric base layer 234 having a conductive material 240 disposed therein. One type of conductive material 240 comprises copper containing materials such as copper, copper alloys (e.g., copper-based alloys containing at least about 80 weight percent copper), or doped copper. An exemplary dielectric film stack 210 including at least a bottom barrier layer 230, a bulk dielectric layer 220, and a top cap film stack containing a first hard mask layer 222 and a second hard mask layer 224 is sequentially deposited over the dielectric base layer 234 on the surface of the substrate 200. Optionally, the dielectric film stack 210 may include an etch stop layer (not shown) deposited between the bottom barrier layer 230 and the dielectric base layer 234. The etch stop layer may include silicon nitrides, silicon dioxides, tetra-ethyl-ortho-silicate (TEOS) based oxides, silicon carbides, silicon oxycarbide, and the like. In one embodiment, the bottom barrier layer 230 is a low K dielectric material, such as a silicon carbide-based material, e.g., silicon oxy-carbides (SiOC), among others. The bottom barrier layer 230 may further comprise dopants, hydrogen, oxygen, nitrogen, boron or phosphorus, or combinations thereof. A low K dielectric silicon carbide-based material suitable for use as the bottom barrier layer 230 may have a dielectric constant of less than or equal to about 7. One exemplary material for the bottom barrier/liner layer is a Blok™ (barrier low-k) film, which is a silicon carbide film available from Applied Materials, Inc., Santa Clara, Calif.

The bulk dielectric layer 220 is deposited over the bottom barrier layer 230 and may be a low K dielectric material having a dielectric constant less than about 5, (e.g., less than about 4 or less than about 2.5), such as carbon-doped silicon dioxide dielectric materials, organic polymers, organosilicate, organo-silicate glass (OSG) materials, spin-on glass materials, fluorine-doped silicon glass (FSG) materials, or the like that are doped with a carbon-based dopant (e.g., alkyl functional groups). In one embodiment of the invention, the bulk dielectric layer 220 comprises silicon, oxygen, and carbon. The OSG is sometimes referred to as doped silicon dioxide, examples of which are Black Diamond™ I, Black Diamond™ II, and Black Diamond™ III material, which are all available from Applied Materials, Inc. of Santa Clara, Calif.

The top cap film stack may be a capping layer, a hard mask layer, a dual hard mask layer, a etch stop layer, or a polish stop layer, suitable for protecting the underlying dielectric film stack 210 during fabrication. In embodiments where the top cap film stack is a dual hard mask layer, the first hard mask layer 222 or a first cap layer may be a dielectric hard mask material, such as silicon dioxide (SiO₂), silicon oxy-nitride (SiON), silicon carbide (SiC), oxygen-doped silicon carbide (SiOC), silicon nitride (SiN), SiOCN, nitrogen-doped silicon carbide (SiCN), tetra-ethyl-ortho-silicate (TEOS) based oxide or the like that may be etched at a rate that is different from that of the bulk dielectric layer 220 and other dielectric layers, when exposed to an etchant. In one example, the first hard mask layer 222 is a SiOC layer deposited on the bulk dielectric layer 220 to serve as an etch mask during trench etching process. The second hard mask layer 224 or a second cap layer is deposited over the first hard mask layer 222. The second hard mask layer 224 may be a conductive material, a metal material, or metal nitride, that has good etch selectivity with respect to the first hard mask layer 222 and with respect to the bulk dielectric layer 220. The second hard mask layer 224 may comprise a refractory metal nitride, such as a material selected from the group consisting of titanium nitride, tantalum nitride, and tungsten nitride or a refractory metal such as tungsten or titanium. The second hard mask layer 224 could also be formed of dielectric materials, such as amorphous silicon, among others.

During polishing of a substrate having the film stack 210 of FIG. 2, one or more spectra of light reflecting off the substrate surface being polished are measured to obtain one or more spectra for a particular platen revolution. Properties of the spectrum of the reflected light changes as the thickness of the film changes, and particular spectra are exhibited by particular thickness of the film. A computing device may be used to determine, based on one or more of the spectra, whether an endpoint has been reached. However, it has been observed that a significant spectra change may be detected during polishing of the top cap film stacks (e.g., the hardmask layer 222) while there is only a minimal spectra change during polishing of the bulk dielectric layer, resulting in a real-time endpoint determination difficult during polishing of the bulk dielectric layer 220 and the hardmask layer 222. In addition, it has been reported that the interface between the bulk dielectric layer 220 and the hardmask layer 222 is not detected or obvious from an image even if using a microscopy technique such as transmission electron microscope (TEM) method. Therefore, various methods utilizing an improved spectra analysis have been proposed to address these issues, as will be discussed below in conjunction with FIGS. 3, 4, and 7.

FIG. 3 shows a method 300 for obtaining a target spectrum according to one embodiment of the present invention. At step 302, a substrate is provided and properties of the substrate having the same pattern as the product substrate are measured. The substrate which is measured is referred to in the instant specification as a “set-up” substrate. The set-up substrate can simply be a substrate that is similar or the same to the product substrate, or the set-up substrate could be one substrate from a batch. The properties can include a pre-polished thickness of a film of interest at a particular location of interest on the substrate. Typically, the thicknesses at multiple locations are measured. The locations are usually selected so that a same type of die feature is measured for each location. Measurement can be performed at a metrology station.

At step 304, the set-up substrate is polished in accordance with a polishing step of interest and spectra of white light reflecting off a substrate surface being polished are collected during polishing. Polishing and spectra collection can be performed at the above described polishing apparatus shown in FIG. 1. Spectra are collected by the in-situ monitoring system during polishing. In one embodiment, the substrate is overpolished, i.e., polished past an estimated endpoint, so that the spectrum of the light that reflected from the substrate can be obtained when the target thickness is achieved.

At step, 306, properties of the overpolished substrate are measured. The properties may include post-polished thicknesses of the film of interest at a particular location or locations used for the pre-polish measurement.

At step 308, the measured thicknesses and the collected spectra are used to select, from among the collected spectra, a spectrum determined to be exhibited by a thickness of interest. In particular, linear interpolation can be performed using the measured pre-polish film thickness and post-polish substrate thicknesses to determine which of the spectra was exhibited when the target film thickness was achieved. The spectrum determined to be the one exhibited when the target thickness was achieved is designated to be the target spectrum for the batch of substrates. Optionally, the spectra collected are further processed to enhance accuracy and/or precision. The spectra can be processed, for example, to normalize them to a common reference, to average them, and/or to filter noise from them.

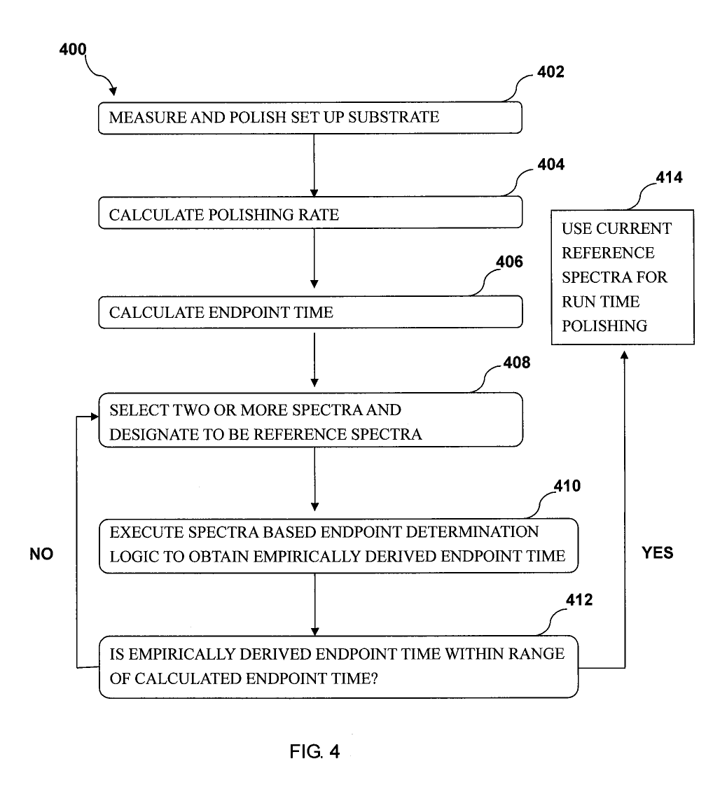

As used herein, a reference spectrum refers to a spectrum that is associated with a target film thickness. The reference spectrum is usually empirically selected for particular endpoint determination logic so that the target thickness is achieved when the computer device calls endpoint by applying the particular spectrum-based endpoint logic. The reference spectrum can be iteratively selected, as will be described below in reference to FIG. 4. It should be noted that the reference spectrum is usually not the target spectrum. Rather, the reference spectrum is usually the spectrum of the light reflected from the substrate when the film of interest has a thickness greater than the target thickness.

FIG. 4 shows a method 400 in accordance with the present invention for selecting a reference spectrum for a particular target thickness and particular spectrum-based endpoint determination logic. At step 402, a set-up substrate is measured and polished as described above in steps 302-306. In particular, spectra collected and the time at which each collected spectrum is measured are saved as a library.

At step 404, a polishing rate of the polishing apparatus for the particular set-up substrate is calculated. The average polishing rate PR can be calculated by using the pre and post-polished thicknesses T1, T2, and the actual polish time, PT, e.g., PR=(T2−T1)/PT.

At step 406, an endpoint time is calculated for the particular set-up substrate to provide a calibration point to test the reference spectrum, as discussed below. The endpoint time can be calculated based on the calculated polish rate PR, the pre-polish starting thickness of the film of interest, ST, and the target thickness of the film of interest, TT. The endpoint time can be calculated as a simple linear interpolation, assuming that the polishing rate is constant through the polishing process, e.g., ET=(ST−TT)/PR.

At step 408, one of the collected spectra is selected and designated to be the reference spectrum. The spectrum selected is a spectrum of light reflected from the substrate when the film of interest has a thickness approximately equal to or greater than the target thickness. At step 410, the particular endpoint determination logic is executed in simulation using the spectra collected for the set-up substrate and with the selected spectrum designated to be the reference spectrum. Execution of the logic yields an empirically derived but simulated endpoint time that the logic has determined to be the endpoint.

At step 412, the empirically derived but simulated endpoint time is compared to the calculated endpoint time. If the empirically derived endpoint time is within a threshold range of the calculated endpoint time, then the currently selected reference spectrum is known to generate a result that matches the calibration point. Thus, when the endpoint logic is executed using the reference spectrum in a run-time environment, the system can reliably detect an endpoint at the target thickness. Therefore, the reference spectrum can be treated as the reference spectrum for run time polishing of the other substrates of the batch (step 414) and saved in the library. Otherwise, steps 410 and 412 are repeated as appropriate.

While a library of reference spectra obtained using steps 402-414 is a collection of reference spectra which represent substrates that share a property in common, the property shared in common in a single library may vary across multiple libraries of reference spectra. For example, two different libraries can include reference spectra that represent substrates with two different underlying thicknesses. In addition, even the initial thickness of each substrate in the same batch may vary due to poor controlled film thickness from deposition, which leads to differences in the actual time needed to reach the polishing endpoint. Similarly, the slurry composition, the polishing pad condition, the relative speed between the polishing pad and the substrate, and the load on the substrate can also cause variations in the material removal rate. These variations cause variations in the actual time needed to reach the polishing endpoint even if a reference spectrum has been identified. Therefore, the polishing endpoint cannot be determined merely as a function of reference spectrum corresponding to different film thickness. In order to provide a real-time endpoint monitoring without being influenced by wafer-to-wafer variability, the present inventors have discovered that spectra collected and the polishing time at which each collected spectrum is measured may be saved in a library and used to identify one or more film interfaces in a target film stack. A signal containing information regarding the film interface between different layers can then be used for active endpoint determination during polishing of one or more target substrates from the same batch.

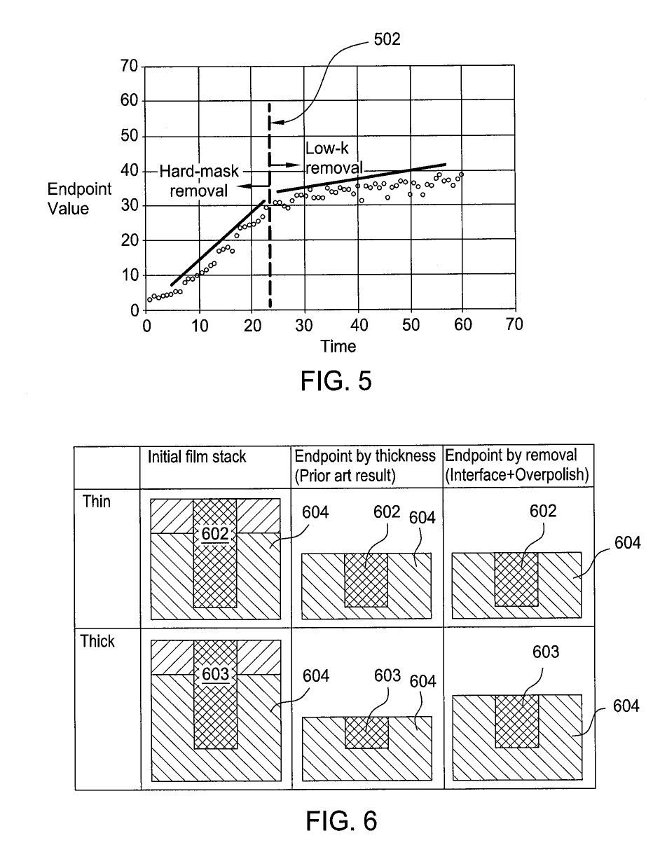

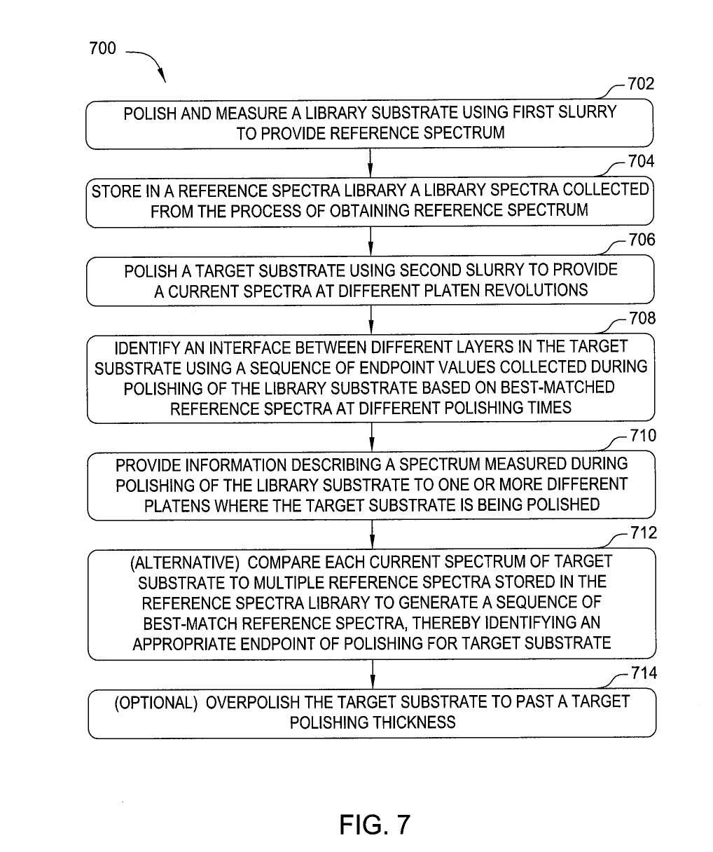

FIG. 5 illustrates a sequence of endpoint values collected during polishing of a target wafer having a known dielectric film stack, for example, the dielectric film stack 210 shown in FIG. 2, at different times. The endpoint value is the library index of the best-matched spectra from the library for the target spectrum at a given time. Each endpoint value represents the time in the polishing process at which index values of reference spectra were collected and particular spectrums are exhibited by particular thicknesses of the film stack 210. By performing the method described in FIG. 7, a significant slope change 502 indicating interface transition is observed when the target wafer was polished with different low-k/hard-mask film selectivity. As will be discussed below, once the film interface is identified, a signal that carries information describing a spectrum measured during polishing may be sent to one or more different platens in which a target wafer is being polished. The target wafer is then optionally overpolished, i.e., polished past a target thickness or a desired thickness to endpoint the polishing, depending upon the application. Compared to the conventional approach where the polishing endpoint is determined as a function of predetermined polishing time or thickness, the present invention enables identifying a film interface transition (and therefore a precise polishing endpoint detection) by polishing the reference and target substrates with different film selectivity. The polishing process according to the present invention is also capable of keeping metal line thickness in a dielectric base layer of a target substrate constant regardless of the initial thickness of the substrate. That is, the resulting thickness of the metal line 602, 603 in the respective dielectric base layer 604 will remain constant regardless of the initial thickness of the incoming substrate, as shown in FIG. 6.

FIG. 7 shows a method 700 in accordance with the present invention for endpoint detection using identified film interface between different layers. It should be noted that the number and sequence of steps illustrated in FIG. 7 are not intended to limiting as to the scope of the invention described herein, since one or more steps can be added, deleted and/or reordered without deviating from the basic scope of the invention described herein.

At step 702, a library (or reference) substrate is polished and measured as described above in steps 402-414 of method 400 using a first slurry to provide a reference spectrum. In this embodiment, the library substrate may be provided with a dual damascene structure as discussed above in FIG. 2, although any other semiconductor devices or integrated circuits are possible.

At step 704, the spectra collected from the process of obtaining the reference spectrum and the time at which each collected spectrum is measured are stored in a library. The library can be implemented in memory of the computing device of the polishing apparatus as discussed above, or made available or provided as digital information to fabricators for use in other polishing systems. In cases where multiple library substrates are desired, spectra for different libraries can be generated by polishing multiple library substrates with different substrate properties (e.g., underlying layer thicknesses or layer composition) and collecting spectra as discussed above. The spectra from one library substrate can provide a first library and the spectra from another substrate with a different underlying layer thickness can provide a second library, and so on.

In some implementations, each reference spectrum is assigned an index value. This index can be the value representing the time in the polishing process at which the reference spectrum is expected to be observed. The spectra can be indexed so that each spectrum in a particular library has a unique index value. The indexing can be implemented so that the index values are sequenced in an order in which the spectra were measured. An index value can be selected to change monotonically, e.g., increase or decrease, as polishing progresses. In particular, the index values of the reference spectra can be selected so that they form a linear function of time or number of platen rotations. For example, the index values can be proportional to a number of platen rotations. Each index number can be a whole number, and the index number can represent the expected platen rotation at which the associated spectrum would appear.

At step 706, one or more target substrates from a batch of substrates are polished. Similar to the library substrate, the target substrate may include a dual damascene structure as discussed above in FIG. 2, although any other semiconductor devices or integrated circuits may be processed utilizing the method 700. During polishing, one or more spectra are measured to obtain current spectra of the target substrate at different platen revolutions using steps 302-306 of method 300 discussed above. In one embodiment, the target substrate is polished using a second slurry which has a low-k removal rate much lower than the first slurry, although the first and second slurries may have similar barrier/hard-mask polish rate. For example, the library substrate may be polished with a removal rate of about 800 Å/min for the cap layer or hard mask layers 222, 224 and a removal rate of about 800 Å/min for the bulk dielectric layer 220 (film selectivity 1:1 for hardmask/bulk dielectric). The target substrate may be polished with a removal rate of 800 Å/min for the cap layer or hard mask layers 222, 224 and a removal rate of about 400 Å/min for the bulk dielectric layer 220 (film selectivity 2:1 for hardmask/bulk dielectric). It is contemplated that the slurry can be any slurry that is capable of creating selectivity difference. One suitable slurry may include acidic slurry or basic slurry with high ultra low-k removal rate or low ultra low-k removal rate. The slurry may also buffer the solution to maintain a desired pH level for processing a substrate. Different slurries from the same company can also have different selectivity depending on how they are formulated and the additives in the slurry, etc.

At step 708, an interface between different layers in a target substrate is identified using a sequence of endpoint values collected during polishing of the library substrate based on a sequence of best-matched reference spectra. The best-matched reference spectra may be obtained by polishing the target substrate with a slurry that has low-k/hard-mask film removal rate different from a slurry used for the library substrate as discussed above. In certain examples, the library substrate is polished and measured post polish thickness before polishing the target substrate. The use of different slurry is one of approaches to create a film selectivity difference between the layers. When the target substrate is being polished, the computing device of the polishing apparatus will search for the library or reference spectra that best matched the target spectra at different polishing times. For example, during the hardmask polishing in the first 30 seconds of the total polish, a specific time t1 of target substrate polish should match well with time t1 of the library substrate polish due to similar thickness, film properties, and spectra. However, during the bulk dielectric layer 220 polishing, time t2 of target substrate polish would match at a different time, for example, time t3 of the library substrate polishing due to their different film properties. These best-matched reference spectra at different polishing times may be represented by numerous dots as shown in FIG. 5. Accordingly, by creating a selectivity difference in film removal rate between the library and target substrates, a significant slope change 502 indicating an interface transition (i.e., film interface) can be observed, as shown in FIG. 5. As the film interface is obtained, an appropriate endpoint of polishing may be identified for the target substrate.

At step 710, once the film interface is identified, an endpoint algorithm based on spectra and thickness data obtained from polishing of the library substrate may be established and sent to one or more different platens where the target substrate is being polished.

At step 712, additionally or alternatively, a comparison module may be used to compare each current spectrum obtained from the sequence of current spectra of the target substrate to a plurality of reference spectra stored in the reference spectra library to generate a sequence of best-matched reference spectra, thereby identifying an appropriate endpoint of polishing for target substrate. In such a case, the polishing of the target substrate may be held until the library substrate is done with the polishing and spectrum measuring. An endpoint algorithm is then established for polishing of the target substrate based on the reference spectra and thickness data obtained during polishing of the library substrate.

At step 714, the target wafer may be optionally overpolished, i.e., polished past a target thickness, depending upon integration scheme and application. This may occur when the manufacturers wish the polishing to stop inside the bulk dielectric layer 220, instead of at the interface. Compared to the conventional approach where the polishing endpoint is determined as a function of predetermined polishing time or thickness, the present invention enables identifying a film interface transition (and therefore a precise polishing endpoint detection) by polishing a reference and target substrate with different film selectivity. The polishing process according to the present invention is also capable of keeping constant metal line thickness in a dielectric base layer regardless of the initial thickness of the substrate.

While the foregoing is directed to embodiments of the present invention, the present invention may be used in other process control that needs to detect film interface other. Further embodiments of the invention may be devised without departing from the basic scope thereof, and the scope thereof is determined by the claims that follow.

1. A method of detecting an endpoint for a target substrate during chemical mechanical polishing process, comprising:
polishing one or more reference substrates at a first film removal rate to provide reference spectra;
polishing one or more target substrates at a second film removal rate to provide current spectra of the one or more target substrates, wherein the second film removal rate is different from the first film removal rate;
identifying an interface transition between different layers formed on the one or more target substrates using a sequence of endpoint values obtained based on the reference spectra collected during polishing of the one or more reference substrates; and
comparing each current spectrum obtained from current spectra of the one or more target substrates to the reference spectra to obtain the sequence of endpoint values.

2. The method of claim 1, wherein the one or more reference substrates and target substrates are polished using different slurry.

3. The method of claim 2, wherein the slurry used for polishing the one or more target substrates has a low-k material removal rate lower than that of the slurry used for polishing the one or more reference substrates.

4. The method of claim 1, further comprising:
after the film interface of the one or more reference substrates is identified, providing a signal that carries information describing a spectrum measured during polishing of the reference substrate to one or more different platens where the target substrate is being polished.

5. The method of claim 1, wherein the comparing each current spectrum obtained from current spectra of the one or more target substrates to the sequence of endpoint values further comprise:
identifying an interface transition between different layers formed on the one or more target substrates based on a sequence of best-matched reference spectra.

6. The method of claim 1, wherein the polishing one or more target substrates further comprises:
polishing a hardmask layer and a low-k dielectric layer formed over the one or more target substrates with a different film removal rate.

7. The method of claim 6, wherein the ratio of the film removal rate for the hardmask layer to the film removal rate for the low-k dielectric layer is at least about 2:1.

8. The method of claim 5, further comprising:
after identifying the interface transition between different layers formed on the one or more target substrates, overpolishing the one or more target substrates to pass a target polishing thickness.

9. The method of claim 1, further comprising:
after polishing one or more reference substrates, establishing an endpoint algorithm to be used for polishing of the one or more target substrates based on the reference spectra and thickness data obtained during polishing of the one or more reference substrates.

10. The method of claim 1, wherein each of the one or more reference substrates or target substrates has a dual damascene structure formed thereon.

11. The method of claim 10, wherein the dual damascene structure further comprising:
a conductive material layer formed in a dielectric base layer; and
a bottom barrier layer formed over a surface of the dielectric base layer;
a bulk low-k dielectric layer formed over the bottom barrier layer; and
a top cap film stack formed over the bulk low-k dielectric layer, wherein the top cap film stack has at least one hardmask layer.

12. The method of claim 11, wherein the bottom barrier layer comprises a doped or undoped silicon carbide-based material.

13. The method of claim 11, further comprising:
an etch stop layer deposited between the bottom barrier layer and the dielectric base layer.

14. The method of claim 13, wherein the etch stop layer comprises silicon nitrides, silicon dioxides, tetra-ethyl-ortho-silicate (TEOS) based oxides, silicon carbides, or silicon oxycarbide.

15. A method of detecting an endpoint for a target substrate during chemical mechanical polishing process, comprising:
polishing a target substrate containing multiple film layers deposed thereon; and
terminating polishing of the target substrate when an endpoint is reached, the endpoint selected in response to information compiled from spectral analysis identifying at least one interface between layers during polishing of at least one reference substrate.

16. The method of claim 15, further comprising:
collecting reference spectra during polishing of at least one reference substrates; and
providing collected reference spectra to one or more different platens where the target substrate is being polished.

17. The method of claim 16, wherein a slurry used for polishing the target substrate has a low-k material removal rate lower than that of a slurry used for polishing the reference substrate.

18. A method for processing a target substrate during chemical mechanical polishing process, comprising:
polishing and measuring a reference substrate using a first slurry to provide reference spectra at different platen revolutions;
polishing and measuring a target substrate using a second slurry to provide current spectra at different platen revolutions, wherein the second slurry has a film removal rate different from that of the first slurry;
comparing current spectra of the target substrate to reference spectra to generate a sequence of best-matched reference spectra at different polishing times; and
identifying an interface transition between different layers in the target substrate using a sequence of endpoint values collected during polishing of the reference substrate based on the sequence of best-matched reference spectra.

19. The method of claim 18, wherein the second slurry has a low-k material removal rate lower than that of the first slurry.

20. The method of claim 18, further comprising:
after identifying the interface transition between different layers in the target substrate, overpolishing the target substrate to past a target polishing thickness.
